(19) United States
(12) Patent Application Publication
(10) Pub. No.: US 2025/0273017 A1
(43) Pub. Date: Aug. 28, 2025

(54) VEHICLE CONTROL APPARATUS, SYSTEM THEREOF, AND METHOD THEREOF

(71) Applicants: HYUNDAI MOTOR COMPANY, Seoul (KR); Kia Corporation, Seoul (KR)

(72) Inventors: Yoo Hong JANG, Hwaseong-si (KR); Yoon Sung CHOI, Hwaseong-si (KR); Sang Jin LEE, Hwaseong-si (KR); Hyo Kyung LEE, Hwaseong-si (KR); Yo Han BAEK, Hwaseong-si (KR)

(73) Assignees: HYUNDAI MOTOR COMPANY, Seoul (KR); Kia Corporation, Seoul (KR)

(21) Appl. No.: 18/930,584

(22) Filed: Oct. 29, 2024

(30) Foreign Application Priority Data
Feb. 28, 2024 (KR) 10-2024-0029181

(51) Int. Cl. G07C 5/00; B60L 58/12; B60L 58/16; H01M 10/42; H01M 10/46; H01M 10/48; H01M 10/613; H01M 10/617; H01M 10/625; H02J 7/00

(52) U.S. Cl. CPC G07C 5/008; H01M 10/425; H01M 10/46; H01M 10/482; H01M 10/613; H01M 10/617; H01M 10/625; H02J 7/0048; B60L 58/12; B60L 58/16; H01M 2010/4271; H01M 2220/20

(57) ABSTRACT

A vehicle control apparatus may include a communication circuit, a battery including battery cells, and a processor. The processor transmits at least one characteristic value among standard deviations of voltages of the battery cells, standard deviations of temperatures of the battery cells, standard deviations of states of charge (SOCs) of the battery cells, or standard deviations of states of health (SOHs) of the battery cells, or any combination to a server via the communication circuit, receive a signal for updating or activating a self-diagnosis protocol for identifying whether there is an anomaly in the battery cell or the battery via the communication circuit from the server, based on that the at least one characteristic value is included in a specified top percentage of characteristic values corresponding to the at least one characteristic value and obtained from other vehicle control apparatuses, and updates or activates the self-diagnosis protocol.

### CROSS-REFERENCE TO RELATED APPLICATION

The present application claims priority to Korean Patent Application No. 10-2024-0029181, filed on Feb. 28, 2024, the entire contents of which is incorporated herein for all purposes by this reference.

### BACKGROUND OF THE PRESENT DISCLOSURE

### Field of the Present Disclosure

The present disclosure relates to a vehicle control apparatus, a system thereof, and a method thereof, and more particularly, relates to technologies for determining an anomaly in a battery.

### Description of Related Art

An electric vehicle technology charges and stores power by a battery. Because the charging speed of the battery and the life of the battery are directly related to the performance of an electric vehicle, as the electric vehicle technology is developed, the importance of a high-performance battery is being emphasized.

To increase a driving distance and decrease a charging time, a battery performance improvement technology and a battery stability improvement technology for increasing the life of the battery and monitoring a risk situation have been rapidly developed.

A vehicle control apparatus may previously detect a symptom of the battery before a safety issue occurs and may diagnose the state of the battery to monitor the state of the battery, by the advancement of a battery management system, for example, the stability improvement technology.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a vehicle control apparatus for diagnosing an anomaly in a battery cell or a battery, a system thereof, and a method thereof.

Another aspect of the present disclosure provides a vehicle control apparatus for monitoring and diagnosing a battery to reduce the risk of battery fire, a system thereof, and a method thereof.

Another aspect of the present disclosure provides a vehicle control apparatus for easily setting a diagnosis threshold of a battery, a system thereof, and a method thereof.

Another aspect of the present disclosure provides a vehicle control apparatus for performing a battery diagnosis by big data to improve the accuracy of the battery diagnosis, a system thereof, and a method thereof.

Another aspect of the present disclosure provides a vehicle control apparatus for diagnosing a battery, while proceeding with charging to improve a user experience, a system thereof, and a method thereof.

Another aspect of the present disclosure provides a vehicle control apparatus for continuously monitoring and diagnosing a battery system to prevent fire, a system thereof, and a method thereof.

Another aspect of the present disclosure provides a vehicle control apparatus for setting an appropriate diagnosis threshold depending on a configuration of a battery system, which rapidly changes, a system thereof, and a method thereof.

Another aspect of the present disclosure provides a vehicle control apparatus for reducing resources necessary to monitor a battery, a system thereof, and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a vehicle control apparatus may include a communication circuit, a battery including battery cells, and a processor.

According to an exemplary embodiment of the present disclosure, the processor is configured to transmit at least one characteristic value among standard deviations of voltages of the battery cells, standard deviations of temperatures of the battery cells, standard deviations of states of charge (SOCs) of the battery cells, or standard deviations of states of health (SOHs) of the battery cells, or any combination thereof to a server via the communication circuit, may receive a signal for updating or activating a self-diagnosis protocol for identifying whether there is an anomaly in the battery cells or the battery via the communication circuit from the server, based on that the at least one characteristic value is included in a predetermined top percentage of characteristic values corresponding to the at least one characteristic value and obtained from other vehicle control apparatuses, may update the self-diagnosis protocol or activate the self-diagnosis protocol, and may perform charging depending on the self-diagnosis protocol, in charging the battery.

According to an exemplary embodiment of the present disclosure, the processor is configured to perform charging depending on the self-diagnosis protocol, if charging the battery, may transmit at least one of a resistance deviation of each of the battery cells, the resistance deviation being obtained according to the updated or activated self-diagnosis protocol, a change in voltage of each of the battery cells during a predetermined time, the change in voltage being obtained according to the updated or activated self-diagnosis protocol, at least one value according to the resistance deviation, the at least one value being obtained according to the updated or activated self-diagnosis protocol, or at least one value according to the change in voltage, the at least one value being obtained according to the updated or activated self-diagnosis protocol, or any combination thereof to the server via the communication circuit, while charging the battery, may receive a signal indicating the anomaly in the battery cells or the battery via the communication circuit from the server, based on at least one of that the resistance deviation is included in a predetermined resistance deviation range, that the change in voltage is included in a predetermined voltage change range, the at least one value according to the resistance deviation, the at least one value according to the change in voltage, or any combination thereof, and may represent the anomaly in the battery cells or the battery to a user.

According to an exemplary embodiment of the present disclosure, the processor may rest the battery until a difference between a highest temperature and a lowest temperature among the temperatures of the battery cells is within a predetermined temperature difference, before charging the battery, may charge the battery with a first current by a predetermined SOC value, based on that the difference between the highest temperature and the lowest temperature is within the predetermined temperature difference, may rest the battery during a predetermined first time interval, from that the battery is charged by the predetermined SOC value, and obtain the resistance deviation of each of the battery cells, based on charging the battery with a second current greater than the first current during a predetermined second time interval, from that the predetermined first time interval elapses, may repeat charging the battery with the first current by the predetermined SOC value, resting the battery during the predetermined first time interval, charging the battery with the second current, and charging the battery during the predetermined second time interval, until an SOC value of the battery is included in a predetermined SOC range indicating charging completion, and may obtain the change in voltage of each of the battery cells during the predetermined time, based on resting the battery during a predetermined third time interval, from that the SOC value of the battery is included in the predetermined SOC range indicating the charging completion. Resting the battery may indicate stopping supplying current provided from the outside of a host vehicle to the battery to charge the battery.

According to an exemplary embodiment of the present disclosure, the processor may rest the battery or may adjust the temperatures of the battery cells by a cooling device provided in a host vehicle so that a difference between a highest temperature and a lowest temperature among the temperatures of the battery cells is within a predetermined temperature difference, before charging the battery.

According to an exemplary embodiment of the present disclosure, the processor may obtain the resistance deviation of each of the battery cells depending on at least one of a change in voltage of each of the battery cells according to the second current or resistance of each of the battery cells, or any combination thereof, based on charging the battery with the second current during the predetermined second time interval, from that the predetermined first time interval elapses.

According to an exemplary embodiment of the present disclosure, the processor may obtain the resistance deviation of each of the battery cells to identify the anomaly in the battery cells or the battery due to a cause rather than an anomaly in electrolyte or active material included in the battery, during the predetermined first preliminary time interval, from that the battery starts to be charged with the second current, and may obtain the resistance deviation of each of the battery cells to identify the anomaly in the battery cells or the battery due to the anomaly in electrolyte or active material included in the battery, during the predetermined second preliminary time interval, from that the predetermined first preliminary time interval elapses. The predetermined second preliminary time interval may be identified according to a value obtained by subtracting the predetermined first preliminary time interval from the predetermined second time interval.

According to an exemplary embodiment of the present disclosure, the processor may obtain the resistance deviation of each of the battery cells to identify the anomaly in the battery cells or the battery due to a current path, while charging the battery with an SOC smaller than a reference SOC using the second current, and may obtain the resistance deviation of each of the battery cells to identify the anomaly in the battery cell or the battery due to the inside of the battery, while charging the battery with an SOC greater than the reference SOC using the second current.

According to an exemplary embodiment of the present disclosure, the processor may adjust a temperature of the battery or temperatures of at least some battery cells to be a predetermined temperature or higher, in resting the battery during the predetermined third time interval.

According to an exemplary embodiment of the present disclosure, the processor may obtain the change in voltage during a predetermined third preliminary time interval to identify at least one battery cell with resistance greater than resistance of other battery cells among the battery cells, from that the SOC value of the battery is included in the SOC range indicating the charging completion, may obtain a change in voltage during a predetermined fourth preliminary time interval to identify at least one battery cell in which there is a short circuit in an internal circuit among the battery cells, during the predetermined fourth preliminary time interval, from that the predetermined third preliminary time interval elapses. The predetermined fourth preliminary time interval may be identified according to a value obtained by subtracting the predetermined third preliminary time interval from the predetermined third time interval.

According to an exemplary embodiment of the present disclosure, the at least one battery cell in which there is the short circuit in the internal circuit among the battery cells may be identified according to a change in SOC value of each of the battery cells, the change in SOC corresponding to an open circuit voltage (OCV) of each of the battery cells, based on obtaining the change in voltage including the OCV.

According to an exemplary embodiment of the present disclosure, the resistance deviation range may be determined based on a resistance deviation of each of battery cells included in the other vehicle control apparatuses. The voltage change range may be determined based on a change in voltage of each of the battery cells included in the other vehicle control apparatuses.

According to another aspect of the present disclosure, a vehicle control system may include a vehicle control apparatus and a server. A processor included in the vehicle control apparatus may transmit at least one characteristic value among standard deviations of voltages of battery cells in a battery included in the vehicle control apparatus, standard deviations of temperatures of the battery cells, standard deviations of states of charge (SOCs) of the battery cells, or standard deviations of states of health (SOHs) of the battery cells, or any combination to the server via a communication circuit included in the vehicle control apparatus, may receive a signal for updating or activating a self-diagnosis protocol for identifying whether there is an anomaly in the battery cells or the battery via the communication circuit included in the vehicle control apparatus from the server, may update the self-diagnosis protocol or activate the self-diagnosis protocol, and may perform charging depending on the self-diagnosis protocol, in charging the battery. A processor included in the server may transmit the signal for updating or activating the self-diagnosis protocol to the vehicle control apparatus via a communication circuit included in the server, based on that the at least one characteristic value is included in a predetermined top percentage of characteristic values corresponding to the at least one characteristic value and obtained from other vehicle control apparatuses.

According to an exemplary embodiment of the present disclosure, the processor included in the vehicle control apparatus may perform charging depending on the self-diagnosis protocol, if charging the battery, may transmit at least one of a resistance deviation of each of the battery cells, the resistance deviation being obtained according to the updated or activated self-diagnosis protocol, a change in voltage of each of the battery cells during a predetermined time, the change in voltage being obtained according to the updated or activated self-diagnosis protocol, at least one value according to the resistance deviation, the at least one value being obtained according to the updated or activated self-diagnosis protocol, or at least one value according to the change in voltage, the at least one value being obtained according to the updated or activated self-diagnosis protocol, or any combination thereof to the server via the communication circuit included in the vehicle control apparatus, while charging the battery, may receive a signal indicating the anomaly in the battery cells or the battery via the communication circuit included in the vehicle control apparatus from the server, and may represent the anomaly in the battery cells or the battery to a user. The processor included in the server may receive the at least one of the resistance deviation, the change in voltage, the at least one value according to the resistance deviation, or the at least one value according to the change in voltage, or the any combination thereof via the communication circuit included in the server from the vehicle control apparatus and may transmit the signal indicating the anomaly in the battery cells or the battery to the vehicle control apparatus via the communication circuit included in the server, based on identifying at least one of that the resistance deviation is included in a predetermined resistance deviation range, that the change in voltage is included in a predetermined voltage change range, the at least one value according to the resistance deviation, or the at least one value according to the change in voltage, or any combination thereof.

According to an exemplary embodiment of the present disclosure, in the vehicle control system, the processor included in the server may identify the anomaly in the battery cells or the battery due to a cause rather than an anomaly in electrolyte or active material included in the battery, based on the resistance deviation obtained during the predetermined first preliminary time interval, from that the battery starts to be charged with a second current greater than a first current charged in the battery by a predetermined SOC value, and may identify the anomaly in the battery cells or the battery due to the anomaly in electrolyte or active material included in the battery, based on the resistance deviation obtained during the predetermined second preliminary time interval, from that the predetermined first preliminary time interval elapses.

According to an exemplary embodiment of the present disclosure, in the vehicle control system, the processor included in the server may identify at least one battery cell with resistance greater than other battery cells among the battery cells, based on the change in voltage obtained during a predetermined third preliminary time interval, from that an SOC value of the battery is included an SOC range indicating charging completion, and may identify at least one battery cell in which there is a short circuit in an internal circuit among the battery cells, based on the change in voltage obtained during a predetermined fourth preliminary time internal, from that the predetermined third preliminary time interval elapses.

According to an exemplary embodiment of the present disclosure, in the vehicle control system, the processor included in the server may identify the at least one battery cell in which there is the short circuit in the internal circuit among the battery cells depending on an SOC value of each of the battery cells, the SOC corresponding to an OCV of each of the battery cells, the OCV being included in the change in voltage, based on the OCV.

According to an exemplary embodiment of the present disclosure, the processor included in the server may be configured to determine the resistance deviation range based on a resistance deviation of each of battery cells included in other vehicle control apparatuses and may be configured to determine the voltage change range based on a change in voltage of each of the battery cells included in the other vehicle control apparatuses.

According to another aspect of the present disclosure, a vehicle control method may include transmitting at least one characteristic value among standard deviations of voltages of battery cells in a battery included in the vehicle control apparatus, standard deviations of temperatures of the battery cells, standard deviations of states of charge (SOCs) of the battery cells, or standard deviations of states of health (SOHs) of the battery cells, or any combination to a server via a communication circuit, receiving a signal for updating or activating a self-diagnosis protocol for identifying whether there is an anomaly in the battery cells or the battery via the communication circuit from the server, based on that the at least one characteristic value is included in a predetermined top percentage of characteristic values corresponding to the at least one characteristic value and obtained from other vehicle control apparatuses, updating the self-diagnosis protocol or activating the self-diagnosis protocol, and performing charging depending on the self-diagnosis protocol, in charging the battery.

According to an exemplary embodiment of the present disclosure, the vehicle control method may further include performing charging depending on the self-diagnosis protocol, if charging the battery, transmitting at least one of a resistance deviation of each of the battery cells, the resistance deviation being obtained according to the updated or activated self-diagnosis protocol, a change in voltage of each of the battery cells during a predetermined time, the change in voltage being obtained according to the updated or activated self-diagnosis protocol, at least one value according to the resistance deviation, the at least one value being obtained according to the updated or activated self-diagnosis protocol, or at least one value according to the change in voltage, the at least one value being obtained according to the updated or activated self-diagnosis protocol, or any combination thereof to the server via the communication circuit, while charging the battery, receiving a signal indicating the anomaly in the battery cells or the battery via the communication circuit from the server, based on at least one of that the resistance deviation is included in a predetermined resistance deviation range, that the change in voltage is included in a predetermined voltage change range, the at least one value according to the resistance deviation, or the at least one value according to the change in voltage, or any combination thereof, and representing the anomaly in the battery cells or the battery to a user.

According to an exemplary embodiment of the present disclosure, the transmitting of the at least one of the resistance deviation of each of the battery cells, the resistance deviation being obtained according to the updated or activated self-diagnosis protocol, the change in voltage of each of the battery cells during the predetermined time, the change in voltage being obtained according to the updated or activated self-diagnosis protocol, the at least one value according to the resistance deviation, the at least one value being obtained according to the updated or activated self-diagnosis protocol, or the at least one value according to the change in voltage, the at least one value being obtained according to the updated or activated self-diagnosis protocol, or the any combination thereof to the server via the communication circuit, while charging the battery, may include resting the battery until a difference between a highest temperature and a lowest temperature among the temperatures of the battery cells is within a predetermined temperature difference, before charging the battery, charging the battery with a first current by a predetermined SOC value, based on that the difference between the highest temperature and the lowest temperature is within the predetermined temperature difference, resting the battery during a predetermined first time interval, from that the battery is charged by the predetermined SOC value, and obtaining the resistance deviation of each of the battery cells, based on charging the battery with a second current greater than the first current during a predetermined second time interval, from that the predetermined first time interval elapses, repeating charging the battery with the first current by the predetermined SOC value, resting the battery during the predetermined first time interval, charging the battery with the second current, and charging the battery during the predetermined second time interval, until an SOC value of the battery is included in a predetermined SOC range indicating charging completion, and obtaining the change in voltage of each of the battery cells during the predetermined time, based on resting the battery during a predetermined third time interval, from that the SOC value of the battery is included in the predetermined SOC range indicating the charging completion. The resting of the battery may indicate stopping supplying current provided from the outside of a host vehicle to the battery to charge the battery.

According to an exemplary embodiment of the present disclosure, the transmitting of the at least one of the resistance deviation of each of the battery cells, the resistance deviation being obtained according to the updated or activated self-diagnosis protocol, the change in voltage of each of the battery cells during the predetermined time, the change in voltage being obtained according to the updated or activated self-diagnosis protocol, the at least one value according to the resistance deviation, the at least one value being obtained according to the updated or activated self-diagnosis protocol, or the at least one value according to the change in voltage, the at least one value being obtained according to the updated or activated self-diagnosis protocol, or the any combination thereof to the server via the communication circuit, while charging the battery, may include resting the battery or adjusting the temperatures of the battery cells by a cooling device provided in a host vehicle so that a difference between a highest temperature and a lowest temperature among the temperatures of the battery cells is within a predetermined temperature difference, before charging the battery.

According to an exemplary embodiment of the present disclosure, the resting of the battery during the predetermined first time interval, from that the battery is charged by the predetermined SOC value, and the obtaining of the resistance deviation of each of the battery cells, based on charging the battery with the second current greater than the first current during the predetermined second time interval, from that the predetermined first time interval elapses, may include obtaining the resistance deviation of each of the battery cells depending on at least one of a change in voltage of each of the battery cells according to the second current or resistance of each of the battery cells, or any combination thereof, based on charging the battery with the second current during the predetermined second time interval, from that the predetermined first time interval elapses.

According to an exemplary embodiment of the present disclosure, the resting of the battery during the predetermined first time interval, from that the battery is charged by the predetermined SOC value, and the obtaining of the resistance deviation of each of the battery cells, based on charging the battery with the second current greater than the first current during the predetermined second time interval, from that the predetermined first time interval elapses, may include obtaining the resistance deviation of each of the battery cells to identify the anomaly in the battery cells or the battery due to a cause rather than an anomaly in electrolyte or active material included in the battery, during the predetermined first preliminary time interval, from that the battery starts to be charged with the second current, and obtaining the resistance deviation of each of the battery cells to identify the anomaly in the battery cells or the battery due to the anomaly in electrolyte or active material included in the battery, during the predetermined second preliminary time interval, from that the predetermined first preliminary time interval elapses. The predetermined second preliminary time interval may be identified according to a value obtained by subtracting the predetermined first preliminary time interval from the predetermined second time interval.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1A is a block diagram illustrating a configuration of a vehicle control apparatus according to an exemplary embodiment of the present disclosure;

FIG. 1B is a block diagram illustrating a configuration of a vehicle control system according to an exemplary embodiment of the present disclosure;

FIG. 2 illustrates an example of a graph illustrating a criterion for identifying whether at least one characteristic value is included in a top percentage, in a vehicle control apparatus, a vehicle control system, or a vehicle control method according to an exemplary embodiment of the present disclosure;

FIG. 3 illustrates an example of a graph illustrating intensity of a current changed according to a charging time based on a self-diagnosis protocol, in a vehicle control apparatus, a vehicle control system, or a vehicle control method according to an exemplary embodiment of the present disclosure;

FIG. 4 illustrates an example of a battery internal structure including battery cells, in a vehicle control apparatus, a vehicle control system, or a vehicle control method according to an exemplary embodiment of the present disclosure;

FIG. 5 illustrates an example of a degree of change in voltage according to a temperature and an SOC value, in a vehicle control apparatus, a vehicle control system, or a vehicle control method according to an exemplary embodiment of the present disclosure;

FIG. 6 illustrates an example of a degree of change in voltage over time, in a vehicle control apparatus, a vehicle control system, or a vehicle control method according to an exemplary embodiment of the present disclosure;

FIG. 7 illustrates an example of a degree of change in voltage according to a temperature of a battery cell, in a vehicle control apparatus, a vehicle control system, or a vehicle control method according to an exemplary embodiment of the present disclosure;

FIG. 8 illustrates an example of an operation of a vehicle control apparatus for providing a user with an anomaly in a battery cell or a battery, in the vehicle control apparatus, a vehicle control system, or a vehicle control method according to an exemplary embodiment of the present disclosure;

FIG. 9 illustrates an example of signaling between a vehicle control apparatus and a server, in the vehicle control apparatus, a vehicle control system, or a vehicle control method according to an exemplary embodiment of the present disclosure; and

FIG. 10 illustrates a computing system associated with a vehicle control apparatus, a vehicle control system, or a vehicle control method according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the exemplary drawings. In adding the reference numerals to the components of each drawing, it should be noted that the identical component is designated by the identical numerals even when they are displayed on other drawings. Furthermore, a detailed description of well-known features or functions will be ruled out in order not to unnecessarily obscure the gist of the present disclosure.

In describing components of exemplary embodiments of the present disclosure, the terms first, second, A, B, (a), (b), and the like may be used herein. These terms are only used to distinguish one component from another component, but do not limit the corresponding components irrespective of the order or priority of the corresponding components. Furthermore, unless otherwise defined, all terms including technical and scientific terms used herein include the same meaning as being generally understood by those skilled in the art to which the present disclosure pertains. Such terms as those defined in a generally used dictionary are to be interpreted as including meanings equal to the contextual meanings in the relevant field of art, and are not to be interpreted as including ideal or excessively formal meanings unless clearly defined as including such in the present application.

Furthermore, in an exemplary embodiment of the present disclosure, the expression “greater than” or “less than” is used to determine whether a specific condition is satisfied or fulfilled, but is only to represent an example and does not exclude the description “greater than or equal to” or “less than or equal to”. A condition described as being “greater than or equal to” may be replaced with a condition described as being “greater than”, a condition describing as being “less than or equal to” may be replaced with a condition described as being “less than”, and a condition described as being “greater than or equal to and less than” may be replaced with “greater than and less than or equal to”. Furthermore, hereinafter, the expression “A to B” refers to at least one of elements (including B) from A to B (including A).

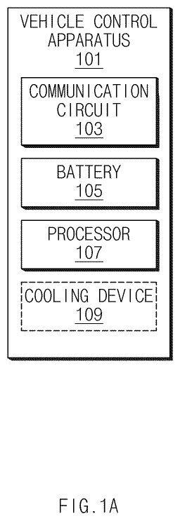

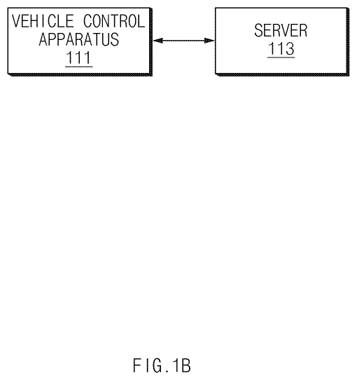

Hereinafter, various exemplary embodiments of the present disclosure will be described in detail with reference to FIGS. 1A to 10.

FIG. 1A is a block diagram illustrating a configuration of a vehicle control apparatus according to an exemplary embodiment of the present disclosure.

Referring to 1A, a vehicle control apparatus 101 may include a communication circuit 103, a battery 105, and a processor 107. The vehicle control apparatus 101 may optionally include a cooling device 109.

The communication circuit 103, the battery 105, the processor 107, and the cooling device 109 may be electronically and/or operably coupled with each other by an electronical component such as a communication bus.

According to an exemplary embodiment of the present disclosure, hereinafter, that pieces of hardware are operably coupled with each other may mean that a direct connection or an indirect connection between the pieces of hardware is established in a wired or wireless manner so that second hardware is controlled by first hardware among the pieces of hardware. Types of the pieces of hardware included in the vehicle control apparatus 101 and/or the number of the pieces of hardware are/is not limited to those shown in FIG. 1A. For example, the vehicle control apparatus 101 may include only some of the hardware components shown in FIG. 1A.

According to an exemplary embodiment of the present disclosure, the processor 107 of the vehicle control apparatus 101 may operate the battery 105 included in a host vehicle by a battery management system (BMS), may be configured for controlling the battery 105 based on contents communicated with another portion in the host vehicle or a server, may obtain measurement values for the battery 105, or may diagnose or estimate a state of the battery 105.

According to an exemplary embodiment of the present disclosure, as the BMS advances, the processor 107 of the vehicle control apparatus 101 may previously detect a symptom of the battery 105 before a safety issue occurs, may diagnose a state of the battery 105, and may monitor the battery 105.

Research for obtaining a state of health (SOH) based on big data and a physical model is conducted as a method for predicting the life of the battery.

A technology for monitoring a basic characteristic of the battery 105 and diagnosing a fine short circuit in a battery cell is developed as the method for previously detecting the symptom of the battery 105. For example, to previously detect the symptom of the battery 105, a technology for diagnosing a state of the battery 105 during charging by the big data has been developed.

According to an exemplary embodiment of the present disclosure, to previously detect the symptom of the battery 105, the processor 107 and the vehicle control apparatus 101 may identify whether a probability that an accident of the host vehicle will occur is greater than a specified probability value and may perform a battery diagnosis by a self-diagnosis protocol, if the probability that the accident of the host vehicle will occur is greater than the specified probability value.

According to an exemplary embodiment of the present disclosure, to identify whether the probability that the accident of the host vehicle will occur is greater than the specified probability value, the processor 107 of the vehicle control apparatus 101 may transmit at least one characteristic value among standard deviations of voltages of battery cells included in the battery 105, standard deviations of temperatures of the battery cells, standard deviations of states of charge (SOCs) of the battery cells, or standard deviations of SOHs of the battery cells, or any combination thereof to a server via the communication circuit 103.

According to an exemplary embodiment of the present disclosure, a processor of the server may identify whether the at least one characteristic value is included in a specified top percentage of characteristic values which correspond to the at least one characteristic value and are obtained from other vehicle control apparatuses. The specified top percentage may be determined based on characteristic values of a vehicle in which an accident occurs. For example, if the vehicle in which the accident occurs is included in a specific percentage (e.g., about top 0.02%), the processor of the server may identify a specified top percentage (e.g., about top 0.2%) based on a value obtained by multiplying the specific percentage by a specific ratio (e.g., about 10 times).

According to an exemplary embodiment of the present disclosure, the processor 107 of the vehicle control apparatus 101 may receive a signal for updating or activating the self-diagnosis protocol for identifying whether there is an anomaly in the battery cell or the battery via the communication circuit 103 from the server.

According to an exemplary embodiment of the present disclosure, the processor 107 of the vehicle control apparatus 101 may update the self-diagnosis protocol or may activate the self-diagnosis protocol. For example, the processor 107 of the vehicle control apparatus 101 may download or update the self-diagnosis protocol from the server via communication (e.g., over-the-air (OTA) communication). For example, the processor 107 of the vehicle control apparatus 101 may activate the self-diagnosis protocol stored in on-board of the vehicle control apparatus 101. If charging the battery 105, the processor 107 of the vehicle control apparatus 101 may perform charging depending on the self-diagnosis protocol.

According to an exemplary embodiment of the present disclosure, while charging the battery 105, the processor 107 of the vehicle control apparatus 101 may obtain at least one of a resistance deviation of each of the battery cells, a change in voltage of each of the battery cells during a specified time, at least one value according to the resistance deviation, or at least one value according to the change in voltage, which is obtained according to the updated or activated self-diagnosis protocol, or any combination thereof.

For example, the at least one value according to the resistance deviation may include a maximum resistance deviation which is a maximum among the resistance deviations of the battery cells and a cell number of a cell with the maximum resistance deviation, but an exemplary embodiment of the present disclosure is not limited thereto. For example, the at least one value according to the change in voltage may include a maximum change in voltage which is a maximum among changes in voltages of the battery cells and a cell number of a cell with the maximum change in voltage, but an exemplary embodiment of the present disclosure is not limited thereto.

According to an exemplary embodiment of the present disclosure, the processor 107 of the vehicle control apparatus 101 may transmit the obtained value to the server via the communication circuit 103.

According to an exemplary embodiment of the present disclosure, the processor of the server may transmit a signal indicating an anomaly in the battery cell or the battery to the vehicle control apparatus 101 via a communication circuit, based on that at least one of that the resistance deviation is included in a specified resistance deviation range, that the change in voltage is included in a specified voltage change range, that the maximum resistance deviation included in the at least one value according to the resistance deviation is included in the specified resistance deviation range, or that the maximum change in voltage included in the at least one value according to the change in voltage is included in the specified voltage change range, or any combination thereof is met.

According to an exemplary embodiment of the present disclosure, the processor of the server may transmit the signal indicating the anomaly in the battery cell or the battery to the vehicle control apparatus 101 via the communication circuit, based on that the resistance deviation which is the maximum among the resistance deviations is greater than or equal to a specified threshold resistance deviation value. As there is a limit to a usage interval of a battery pack due to a battery cell with increased resistance, this is because the capacity of the battery pack may be reduced. The resistance deviation range may be determined based on the threshold resistance deviation value.

According to an exemplary embodiment of the present disclosure, the processor of the server may transmit the signal indicating the anomaly in the battery cell or the battery to the vehicle control apparatus 101 via the communication circuit, based on that the resistance deviation which is the maximum increases to the specific deviation value or more over time. If the resistance deviation gradually increases, as an issue due to a cause such as increased lithium precipitation emerges, this is because there is a high probability of leading to a safety issue over time.

According to an exemplary embodiment of the present disclosure, the processor of the server may transmit the signal indicating the anomaly in the battery cell or the battery to the vehicle control apparatus 101 via the communication circuit, based on that the change in voltage of each of the battery cells during the specified time is greater than or equal to the threshold voltage change value. The voltage change range may be determined based on the threshold voltage change value.

According to an exemplary embodiment of the present disclosure, the processor of the server may transmit the signal indicating the anomaly in the battery cell or the battery to the vehicle control apparatus 101 via the communication circuit, based on that the change in voltage, which is the maximum, increases to the specific voltage change value or more over time.

According to an exemplary embodiment of the present disclosure, the resistance deviation range and the voltage change range may vary with an SOH of the battery.

According to an exemplary embodiment of the present disclosure, the processor of the server may be configured to determine the resistance deviation range based on a resistance deviation of each of battery cells included in other vehicle control apparatuses. The processor of the server may be configured to determine the voltage change range based on a change in voltage of each of the battery cells included in the other vehicle control apparatuses.

For example, the processor of the server may divide vehicle control apparatuses into two groups (e.g., a group in which a fault occurs and a group in which the fault does not occur), based on the number of the vehicle control apparatuses, each of which includes a corresponding value as a maximum resistance deviation value. If graphing the number of the vehicle control apparatuses depending on the maximum resistance deviation value and if the number of the vehicle control apparatuses shows a tendency to decrease and then increase as the maximum resistance deviation value increases, the processor of the server may identify the resistance deviation range, based on the maximum resistance deviation value at a boundary.

For another example, if the vehicle control apparatuses are not divided into the two groups depending on the tendency of the vehicle control apparatus according to the maximum resistance deviation value, the processor of the server may divide the vehicle control apparatuses into two groups, based on a top percentage determined among maximum resistance deviation values of the other vehicle control apparatuses.

For another example, the processor of the server may divide vehicle control apparatuses into two groups, based on the number of the vehicle control apparatuses, each of which includes a corresponding value as a maximum voltage change value. If graphing the number of the vehicle control apparatuses depending on the maximum voltage change value and if the number of the vehicle control apparatuses shows a tendency to decrease and then increase as the maximum voltage change value increases, the processor of the server may identify the resistance deviation range, based on the maximum voltage change value at the boundary.

For another example, if the vehicle control apparatuses are not divided into the two groups depending on the tendency of the vehicle control apparatus according to the maximum voltage change value, the processor of the server may divide the vehicle control apparatuses into two groups, based on a top percentage determined among maximum voltage change values of the other vehicle control apparatuses.

According to an exemplary embodiment of the present disclosure, the cooling device 109 may reduce the temperature of the battery cell or battery.

According to an exemplary embodiment of the present disclosure, the processor 107 of the vehicle control apparatus 101 may represent the anomaly in the battery cells or the battery to a user. For example, the processor 107 of the vehicle control apparatus 101 may provide the user with a notification recommending inspection according to the anomaly in the battery cell or the battery. For example, the processor 107 of the vehicle control apparatus 101 may provide the user with an estimated battery cell and an estimated cause of the anomaly. For example, the processor 107 of the vehicle control apparatus 101 may provide the user with a notification guiding the user to a place where it is able to check the battery. However, an exemplary embodiment of the present disclosure may not be limited thereto.

FIG. 1B is a block diagram illustrating a configuration of a vehicle control system according to an exemplary embodiment of the present disclosure.

Referring to FIG. 1B, the vehicle control system may include a vehicle control apparatus 111 and a server 113. The vehicle control apparatus 111 and the server 113 may transmit and/or receive information associated with a state of a battery through communication.

The vehicle control system may include the vehicle control apparatus 111 and the server 113. Contents of the vehicle control apparatus 111 may refer to contents of a vehicle control apparatus 101 of FIG. 1A. Thus, duplicated contents will be omitted.

According to an exemplary embodiment of the present disclosure, a processor included in the server 113 may receive at least one characteristic value among standard deviations of voltages of battery cells in a battery included in the vehicle control apparatus 111, standard deviations of temperatures of the battery cells, standard deviations of SOCs of the battery cells, or standard deviations of SOHs of the battery cells, or any combination thereof from the vehicle control apparatus 111.

According to an exemplary embodiment of the present disclosure, the processor included in the server 113 may transmit a signal for updating or activating a self-diagnosis protocol to the vehicle control apparatus 111 via a communication circuit included in the server 113, based on that the at least one characteristic value is included in a specified top percentage of characteristic values which correspond to the at least one characteristic value and are obtained from other vehicle control apparatuses.

According to an exemplary embodiment of the present disclosure, the processor included in the server 113 may receive at least one of a resistance deviation, a change in voltage, at least one value according to the resistance deviation, or at least one value according to the change in voltage, or any combination thereof via the communication circuit included in the server 113 from the vehicle control apparatus 111.

According to an exemplary embodiment of the present disclosure, the processor included in the server 113 may transmit a signal indicating an anomaly in the battery cell or the battery to the vehicle control apparatus 111 via the communication circuit included in the server 113, based on that at least one of that the resistance deviation is included in a specified resistance deviation range, that the change in voltage is included in a specified voltage change range, that a maximum resistance deviation included in the at least one value according to the resistance deviation is included in the specified resistance deviation range, or that a maximum change in voltage included in the at least one value according to the change in voltage is included in the specified voltage change range, or any combination thereof is met.

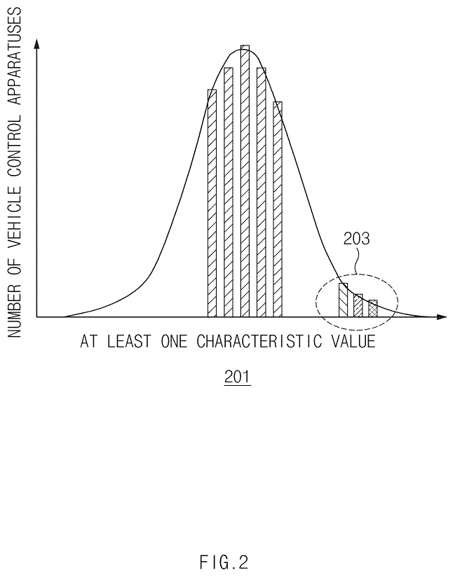

FIG. 2 illustrates an example of a graph illustrating a criterion for identifying whether at least one characteristic value is included in a top percentage, in a vehicle control apparatus, a vehicle control system, or a vehicle control method according to an exemplary embodiment of the present disclosure.

Referring to FIG. 2, a graph 201 may illustrate the number of vehicle control apparatuses with at least one characteristic value.

According to an exemplary embodiment of the present disclosure, to identify whether a probability that the accident of a host vehicle will occur is greater than a specified probability value, a processor of a vehicle control apparatus may transmit at least one characteristic value among standard deviations of voltages of battery cells included in a battery, standard deviations of temperatures of the battery cells, standard deviations of SOCs of the battery cells, or standard deviations of SOHs of the battery cells, or any combination thereof to a server via a communication circuit.

According to an exemplary embodiment of the present disclosure, a processor of the server may identify that the probability that the accident of the host vehicle will occur is greater than the specified probability, based on that the at least one characteristic value is included in a specified top percentage of characteristic values which correspond to the at least one characteristic value and are obtained from other vehicle control apparatuses.

According to an exemplary embodiment of the present disclosure, the processor of the server may identify the specified top percentage, based on various criteria, to identify a vehicle control apparatus in which the probability that the accident will occur is greater than the specified probability, as shown in 203 of FIG. 2. The plurality of data bars 203 may represent the number of the vehicle control apparatus in which the probability that the accident will occur is greater than the specified probability. For example, if a fire accident rate compared to the number of electric vehicles distributed is a specific percentage (e.g., about top 0.2%), the processor of the server may identify the specified top percentage (e.g., about top 0.2%) based on a value obtained by multiplying the specific percentage by a specific ratio (e.g., about 10 times). As an exemplary embodiment of the present disclosure, the fire accident rate compared to the number of the electric vehicles distributed may include a fire accident rate compared to the number of electric vehicles distributed in a specific year as announced by National Fire Agency statistics.

According to an exemplary embodiment of the present disclosure, the processor of the server may transmit a signal for updating or activating a self-diagnosis protocol to the vehicle control apparatus via a communication circuit, based on identifying that a probability that an accident of a host vehicle including the vehicle control apparatus will occur is greater than a specified probability.

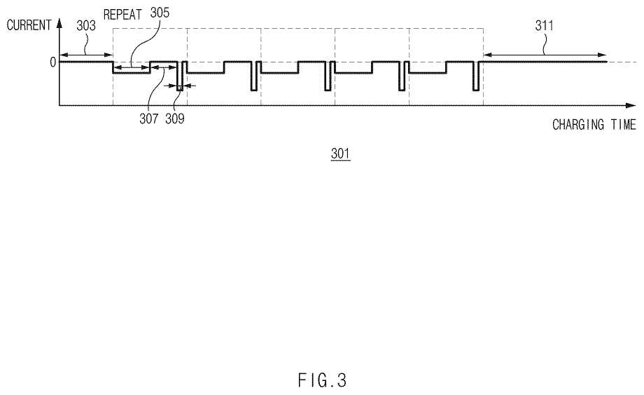

According to an exemplary embodiment of the present disclosure, the processor of the vehicle control apparatus may perform charging depending on the self-diagnosis protocol, during charging a battery, based on receiving the signal for updating or activating the self-diagnosis protocol via the communication circuit. A description will be provided below of contents of performing the charging depending on the self-diagnosis protocol with reference to FIG. 3.

FIG. 3 illustrates an example of a graph illustrating intensity of a current changed according to a charging time based on a self-diagnosis protocol, in a vehicle control apparatus, a vehicle control system, or a vehicle control method according to an exemplary embodiment of the present disclosure.

Referring to FIG. 3, a graph 301 may include a first interval 303, a second interval 305, a third interval 307, a fourth interval 309, and a fifth interval 311.

According to an exemplary embodiment of the present disclosure, while the self-diagnosis protocol is performed, a processor of the vehicle control apparatus may change a magnitude of a current supplied to a battery for charging and may obtain a resistance deviation of each of battery cells or a change in voltage in each of the battery cells.

The processor of the vehicle control apparatus may change the magnitude of the current and may obtain the resistance deviation or the change in voltage. Obtaining the resistance deviation or the change in voltage without changing the magnitude of the current is because the accuracy of a slew rate or a resistance value obtained by irregularity in the signal while driving is able to be reduced.

Furthermore, performing the self-diagnosis protocol, while charging the battery, is because a safety problem is able to occur, because the host vehicle is traveling if performing the self-diagnosis protocol, while the battery is being discharged. In other words, this is because the battery is discharged by any intention of a user due to the safety problem or adjusting a supplied current is able to be limited.

According to an exemplary embodiment of the present disclosure, the processor of the vehicle control apparatus may release the provision of the slew rate, while the battery is charged by the self-diagnosis protocol, thus improving the accuracy of the resistance deviation and the change in voltage.

In a first interval 303, according to an exemplary embodiment of the present disclosure, the processor of the vehicle control apparatus may rest the battery or may adjust temperatures of battery cells by a cooling device (e.g., cooling device 109) provided in the host vehicle, until a difference between the highest temperature and the lowest temperature among the temperatures of the battery cells is within a specified temperature difference, before charging the battery. This is because of increasing the accuracy of diagnose according to the resistance deviation of each of the battery cells.

The battery may include a battery pack including battery cells. The battery cells may be plural in number (e.g., a number between about 100 and about 200). There may be a difference between temperatures of the battery cells depending on a driving state of the host vehicle before charging the battery and a temperature of outside air. Because resistance of each of the battery cells is influenced by a temperature, to increase the accuracy of a diagnosis according to the resistance deviation of each of the battery cells, the processor of the vehicle control apparatus may adjust the temperatures of the battery cells until the difference between the highest temperature and the lowest temperature among the temperatures of the battery cells is within the specified temperature (e.g., about 2° C.). For example, the processor of the vehicle control apparatus may adjust the temperatures of the battery cells by a coolant, in a state in which the temperature of the coolant is set constant.

Furthermore, the resistance of each of the battery cells may vary with an SOC value of each of the battery cells. While the battery is resting, a difference in SOC between the battery cells may be reduced by a balancing circuit. Therefore, the accuracy of the diagnose according to the resistance deviation of each of the battery cells may be improved. However, for a cell in which current is leaked, although the balancing circuit operates, an SOC may be lowered compared to another cell and resistance may be measured to be great. Because the cell in which current is leaked is able to be identified by a resistance deviation or a change in voltage, which is measured later, the processor of the vehicle control apparatus may rest the battery or may fail to adjust SOCs of the battery cells, until a difference between the highest SOC value and the lowest SOC among the SOCs of the battery cells is a specific value.

In a second interval 305, according to an exemplary embodiment of the present disclosure, the processor of the vehicle control apparatus may charge the battery with a first current by a specified SOC (e.g., about 10%), based on that the difference between the highest temperature and the lowest temperature is within the specified temperature. The first current may be supplied to the battery to charge the battery.

In a third interval 307, according to an exemplary embodiment of the present disclosure, the processor of the vehicle control apparatus may rest the battery during a specified first time interval, from that the battery is charged by the specified SOC. The processor of the vehicle control apparatus may rest the battery to relieve a voltage according to polarization (e.g., activation polarization or electrolyte polarization) and may stabilize a voltage of each of the battery cells depending to the voltage relief according to the polarization, thus improving the accuracy of a diagnosis of whether there is an anomaly in the battery cell or the battery.

In a fourth interval 309, according to an exemplary embodiment of the present disclosure, the processor of the vehicle control apparatus may obtain a resistance deviation of each of the battery cells, based on charging the battery with a second current greater than the first current during a specified second time interval, from that the specified first time interval elapses.

Supplying the second current greater than the first current to obtain the resistance deviation of each of the battery cells is to reduce an error of resistance of each of the battery cells according to an error in voltage sensors which measure a voltage of each of the battery cells. In other words, as the magnitude of a current supplied to the battery is large, an error rate of a voltage of each of the battery cells, which is measured by the voltage sensor of each of the battery cells, may be small.

According to an exemplary embodiment of the present disclosure, the processor of the vehicle control apparatus may obtain a resistance deviation of each of the battery cells depending on at least one of a change in voltage of each of the battery cells according to the second current or resistance of each of the battery cells, or any combination thereof, based on charging the battery with the second current.

The processor of the vehicle control apparatus may obtain resistance of each of the battery cells, based on the change in voltage of each of the battery cells according to the second current and the current applied to each of the battery cells. The processor of the vehicle control apparatus may obtain the resistance deviation of each of the battery cells, based on the resistance of each of the battery cells.

According to an exemplary embodiment of the present disclosure, the processor of the vehicle control apparatus may vary the obtained time to obtain the resistance deviation of each of the battery cells. For example, the processor of the vehicle control apparatus may obtain the resistance deviation of each of the battery cells during a specified first preliminary time interval (e.g., about 0.1 seconds), from that the battery starts to be charged with the second current. The processor of the vehicle control apparatus may obtain the resistance deviation of each of the battery cells during a specified second preliminary time interval (e.g., about 10 seconds), from that the specified first preliminary time interval elapses. The specified second preliminary time interval may be identified according to a value obtained by subtracting the specified first preliminary time interval from the specified second time interval.

According to an exemplary embodiment of the present disclosure, a processor of a server may identify an anomaly in the battery cell or the battery due to a cause rather than an anomaly in electrolyte or active material included in the battery by the resistance deviation of each of the battery cells, which is obtained during the specified first preliminary time interval.

According to an exemplary embodiment of the present disclosure, the processor of the server may identify an anomaly in the battery cells or the battery due to the anomaly in electrolyte or active material included in the battery by the resistance deviation of each of the battery cells, which is obtained during the specified second preliminary time interval, from that the specified first preliminary time interval elapses.

According to an exemplary embodiment of the present disclosure, the processor of the vehicle control apparatus may obtain the resistance deviation of each of the battery cells, if the obtained SOC value of the battery cell differs.

For example, while charging a battery cell with an SOC smaller than a reference SOC using the second current, the processor of the vehicle control apparatus may obtain the resistance deviation of each of the battery cells to identify the anomaly in the battery cells or the battery due to a current path.

The accuracy of a diagnosis of identifying an anomaly due to the current path based on resistance of the battery cell with the SOC smaller than the reference SOC may be greater than the accuracy of a diagnosis of identifying an anomaly due to the current path based on resistance of a battery cell with an SOC greater than the reference SOC. This is because the resistance of the battery cell with the SOC smaller than the reference SOC is greater than the resistance of the battery cell with the SOC greater than the reference SOC. Although the same current is applied, because a change in voltage of a battery cell with large resistance is greater than a change in voltage of a battery cell with small resistance, this is because the accuracy of a diagnosis is improved as an error of the voltage sensor decreases. The anomaly in the battery cell or the battery due to the current path may occur due to reasons such as tab folding and poor welding.

For example, while charging the battery cell with the SOC greater than the reference SOC using the second current, the processor of the vehicle control apparatus may obtain a resistance deviation of each of the battery cells to identify an anomaly in the battery cell or the battery due to the inside of the battery.

The accuracy of a diagnosis of identifying the anomaly due to the inside of the battery based on resistance of the battery cell with the SOC greater than the reference SOC may be greater than the accuracy of a diagnosis of identifying an anomaly due to the inside of the battery based on resistance of the battery cell with the SOC smaller than the reference SOC.

This is because volume of an electrode of the battery cell with the SOC greater than the reference SOC is greater than volume of an electrode of the battery cell with the SOC smaller than the reference SOC. The anomaly in the battery cell or the battery due to the inside of the battery may occur due to an increase in an internal resistance of the battery cell, which is caused by lithium precipitation or foreign substances.

According to an exemplary embodiment of the present disclosure, the processor of the vehicle control apparatus may repeatedly perform the operation of the processor of the vehicle control apparatus in the second interval 305, the operation of the processor of the vehicle control apparatus in the third interval 307, and the operation of the processor of the vehicle control apparatus in the fourth interval 309, until the SOC value of the battery is included in a specified SOC range indicating charging completion.

According to an exemplary embodiment of the present disclosure, after performing the operations of the processor of the vehicle control apparatus in the second interval 305, the third interval 307, and the fourth interval 309, the processor of the vehicle control apparatus may rest the battery during a specified time, before repeatedly performing the operations of the processor of the vehicle control apparatus in the second interval 305, the third interval 307, and the fourth interval 309.

According to an exemplary embodiment of the present disclosure, resting the battery may indicate stopping supplying current provided from the outside of the host vehicle to the battery to charge the battery.

In a fifth interval 311, the processor of the vehicle control apparatus may obtain a change in voltage of each of the battery cells during a specified time, based on resting the battery during a third time interval, from that the SOC value of the battery is included in the specified SOC range indicating the charging completion.

According to an exemplary embodiment of the present disclosure, for a battery cell with a short circuit, whether a short circuit occurs and the magnitude of a current may vary with the volume of an electrode of the battery cell. The volume of the electrode of the battery cell may vary with an SOC value of the battery cell and a temperature of the battery cell.

According to an exemplary embodiment of the present disclosure, if resting the battery during a specified third time interval, the processor of the vehicle control apparatus may adjust a temperature of the battery or temperatures of at least some battery cells to be a specified temperature or higher, by a cooling device (e.g., cooling device 109) or a coolant provided in the host vehicle. This is because of increasing the accuracy of a diagnose according to the change in voltage of each of the battery cells.

For a battery cell with a short circuit, as the volume of an electrode decrease as a temperature decreases, a short contact area may become small or a short connection may be released. Therefore, to increase the accuracy of the diagnose, the processor of the vehicle control apparatus may charge the battery and may then adjust a temperature of the battery cell to be a specified temperature to identify whether there is a short circuit, when the battery pack is at a low temperature. Thereafter, the processor of the vehicle control apparatus may transmit a change in voltage of a battery cell which includes the specified temperature or higher to the server via the communication circuit.

For a battery cell with a short circuit, as the volume of an electrode decrease as an SOC is decreases, a short contact area may become small or a short connection may be released. Therefore, to increase the accuracy of the diagnosis, the processor of the vehicle control apparatus may transmit a change in voltage if the SOC value of the battery cell is included in the specified SOC indicating the charging completion to the server via the communication circuit.

According to an exemplary embodiment of the present disclosure, the processor of the vehicle control apparatus may vary the obtained time to obtain a change in voltage of each of the battery cells. For example, the processor of the vehicle control apparatus may obtain a change in voltage of each of the battery cells during a specified third preliminary time interval (e.g., about 1 hour), during the specified third preliminary time interval, from that the battery SOC is included in the SOC range indicating the charging completion.

A change in voltage of at least one battery cell with resistance greater than resistance of other battery cells may be represented as a threshold level or more compared to an average change in voltage, during the specified third preliminary time interval, after that the SOC value of the battery is included in the SOC range indicating the charging completion.

According to an exemplary embodiment of the present disclosure, the processor of the vehicle control apparatus may identify at least one battery cell which there is a short circuit in its an internal circuit among the battery cells by a change in voltage of each of the battery cells, which is obtained during a specified fourth preliminary time interval, from that the specified third preliminary time interval elapses.

A change in voltage of the battery cell with a short circuit may be represented as the threshold level or more compared to the average change in voltage, during the specified fourth preliminary time interval. The specified fourth preliminary time interval may be identified according to a value obtained by subtracting the specified third preliminary time interval from the specified third time interval.

According to an exemplary embodiment of the present disclosure, the processor of the vehicle control apparatus may identify at least one battery cell in which there is a short circuit in its internal circuit among the battery cells, depending on an SOC value of each of the battery cells, which corresponds to an open circuit voltage (OCV) of each of the battery cells, based on obtaining a change in voltage including the OCV.

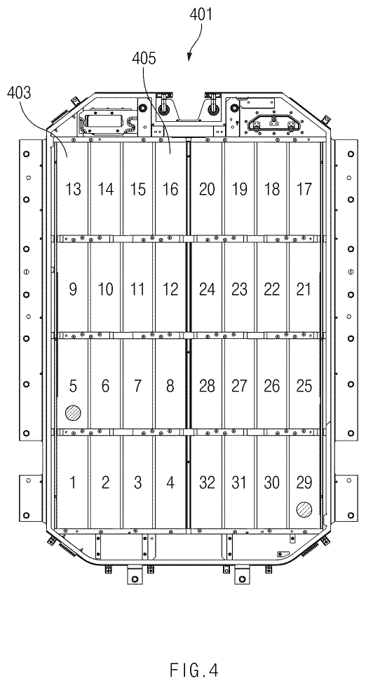

FIG. 4 illustrates an example of a battery internal structure including battery cells, in a vehicle control apparatus, a vehicle control system, or a vehicle control method according to an exemplary embodiment of the present disclosure.

Referring to FIG. 4, a battery 401 may include battery cells. The battery cells may include a first battery cell 403 with the lowest temperature and a second battery cell 405 with the highest temperature. A battery module (e.g., a first battery module including the first battery cell 403 and a second battery module including the second battery cell 405) may include a plurality of battery cells (e.g., about 6 battery cells). The battery cells included in the battery 401 may be plural in number (e.g., a number between about 100 and about 200).

If a temperature of air outside the battery 401 is smaller than a temperature inside the battery 401 or a temperature inside the battery 401 is greater than a temperature of air outside the battery 401 due to driving of a host vehicle, temperatures of the battery cells included in the battery 401 may be different from each other. Because resistance of each of the battery cells is influenced by a temperature, to increase the accuracy of a diagnosis according to the resistance deviation of each of the battery cells, a processor of a vehicle control apparatus may adjust the temperatures of the battery cells until a difference between a temperature of the second battery cell 405 and a temperature of the battery 401 including the first battery cell 403 is within a specified temperature difference (e.g., about 2° C.). For example, the processor of the vehicle control apparatus may adjust the temperatures of the battery cells by a coolant, in a state in which the temperature of the coolant is set constant.

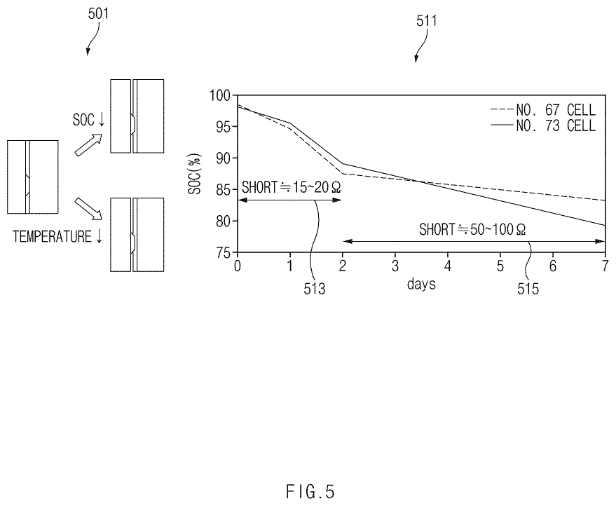

FIG. 5 illustrates an example of a degree of change in voltage according to a temperature and an SOC value, in a vehicle control apparatus, a vehicle control system, or a vehicle control method according to an exemplary embodiment of the present disclosure.

Referring to FIG. 5, a change 501 in battery cell may indicate a change in volume of an electrode according to an SOC value of the battery cell and a temperature of the battery cell. A graph 511 may illustrate a short resistance value according to the SOC value of the battery cell.

According to an exemplary embodiment of the present disclosure, in the change 501 in battery cell, if there is a piece of foreign matter on the positive electrode inside the battery cell, an area of a short and whether the short occurs may vary with the volume of the electrode of the battery cell. The piece of foreign matter may be a foreign matter.

The smaller the SOC value of the battery cell, the more the volume of the electrode of the battery cell may decrease. The smaller the temperature, the more the volume of the electrode of the battery cell may decrease. In other words, for a battery cell with a short circuit, as the SOC is small and the temperature is small, the volume of the electrode may decrease. The short contact area may become small or a short connection may be released.

For example, a short may occur due to the piece of foreign matter in a battery cell in which the SOC is about 100% and the temperature is about 25° C.

The short may fail to occur due to the piece of foreign matter because the volume of the electrode decreases for a battery cell in which the SOC is about 60% and the temperature is about 25° C. than for the battery cell in which the SOC is about 100% and the temperature is about 25° C.

Furthermore, the short may fail to occur due to the piece of foreign matter because the volume of the electrode decreases for a battery cell in which the SOC is about 100% and the temperature is about −7° C. than for the battery cell in which the SOC is about 100% and the temperature is about 25° C.

Therefore, if the SOC value of the battery cell is included in a specified SOC indicating charging completion to increase the accuracy of a diagnose, a processor of the vehicle control apparatus may adjust a temperature of a battery or temperatures of at least some battery cells so that the temperature of the battery cell is greater than or equal to a specified temperature and may measure a change in voltage of the battery cell.

In the reference numeral 513 and 515 of a graph 511, a change in SOC value and short resistance according to a time when the charged battery is rested may be illustrated.

Short resistance (e.g., a value between about 15 (2 and about 20 (2) due to a leakage current of a battery cell with a short circuit in an interval 513 with a relatively large SOC (e.g., an interval where the battery has been rested for 1 day and 2 days) may be smaller than short resistance (e.g., a value between about 50 (and about 100 (2) due to a leakage current of a battery cell with a short circuit in an interval 515 with a relatively small SOC (e.g., an interval where the battery has been rested after 2 days).

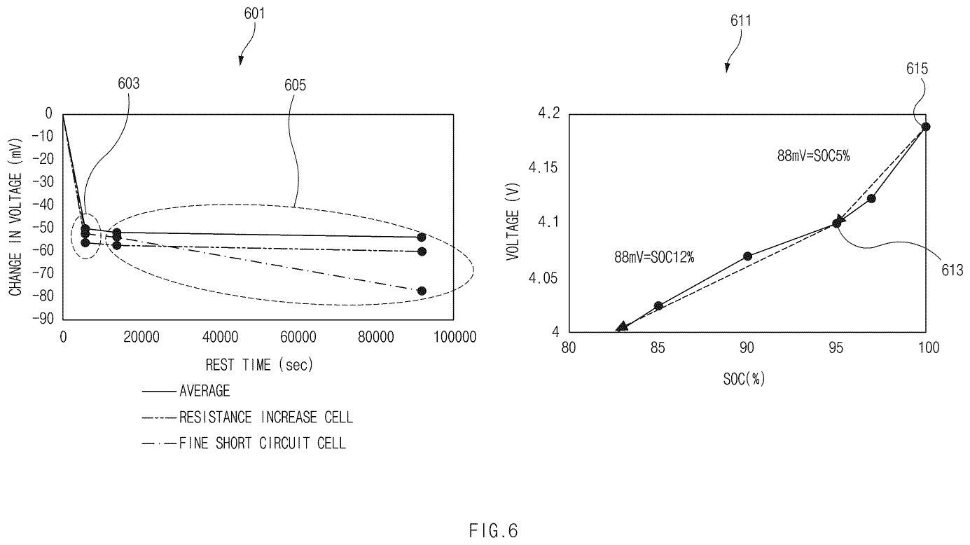

FIG. 6 illustrates an example of a degree of change in voltage over time, in a vehicle control apparatus, a vehicle control system, or a vehicle control method according to an exemplary embodiment of the present disclosure.

Referring to FIG. 6, a first graph 601 may illustrate a change in voltage of a battery cell according to a rest time. A second graph 611 may illustrate a change in voltage according to the amount of change in SOC.

In the first graph 601, the magnitude of the change in voltage of the battery cell may vary with a time when the change in voltage is obtained.

For example, in a first rest interval 603 (e.g., a time interval from about 0 to about 1 hour), a change in voltage of a battery cell with resistance greater than resistance of other battery cells may be greater than a change in voltage of a battery cell in which there is a short circuit in its internal circuit. Therefore, a processor of the vehicle control apparatus may be easy to identify the battery cell with the resistance greater than the resistance of the other battery cells in the first rest interval 603.

For example, the processor of the vehicle control apparatus may obtain a change in voltage of each of the battery cells during a specified third preliminary time interval (e.g., about 1 hour), during the specified third preliminary time interval, from that the SOC value of the battery is included in an SOC range indicating charging completion.

For example, in a second rest interval 605 (e.g., a time interval from about 2 hour), a change in voltage of a battery cell in which there is a short circuit in its internal circuit may be greater than a change in voltage of the battery cell with resistance greater than resistance of other battery cells. Therefore, the processor of the vehicle control apparatus may be easy to identify the battery cell in which there is the short circuit in the internal circuit in the second rest interval 605.

In other words, the processor of the vehicle control apparatus may identify at least one battery cell in which there is a short circuit in its internal circuit among the battery cells by a change in voltage of each of the battery cells, which is obtained during a specified fourth preliminary time interval, from that the specified third preliminary time interval elapses. The specified fourth preliminary time interval may be identified according to a value obtained by subtracting the specified third preliminary time interval from the specified third time interval.

In a second graph 611, a change in SOC value of the battery cell according to a change in voltage may be identified in a battery cell of a voltage smaller than a reference voltage.

According to an exemplary embodiment of the present disclosure, a change in voltage of a battery cell referenced if identifying a battery cell in which there is a short circuit in its internal circuit may be identified from the battery cell with the voltage smaller than the reference voltage.

A first point 613 may indicate that the SOC value of the battery is included in an SOC range indicating charging completion and may indicate a voltage of the battery cell in which there is the short circuit in the internal circuit.

A second point 615 may indicate that the SOC value of the battery is included in the SOC range indicating the charging completion and may indicate a voltage of a battery cell in which there is no short circuit in the internal circuit.

After the SOC value of the battery is included in the SOC range indicating the charging completion, while the battery is rested, the voltage of the battery cell in which there is no short circuit in the internal circuit may drop by about 88 milli-voltage (mV) and the voltage of the battery cell in which there is the short circuit in the internal circuit may drop by about 88 mV.

However, after the SOC value of the battery is included in the SOC range indicating the charging completion, while the battery is rested, the SOC value of the battery cell in which there is no short circuit in the internal circuit may drop by about 5% and the voltage of the battery cell in which there is the short circuit in the internal circuit may drop by about 12%.

Therefore, it may be identified whether the internal circuit of the battery cell is short-circuited according to a change in SOC value of the battery cell, rather than a change in voltage of the battery cell. This is because it is identified that the voltage of the battery cell in which there is the short circuit in the internal circuit of the battery cell is the voltage smaller than the reference voltage. A processor of a server may convert the change in voltage into the change in SOC to secure resolution.

Therefore, at least one battery cell in which there is a short circuit in its internal circuit among the battery cells may be identified according to a change in SOC value of each of battery cells, which corresponds to an open circuit voltage (OCV) of each of the battery cells, based on obtaining a change in voltage, including the OCV.

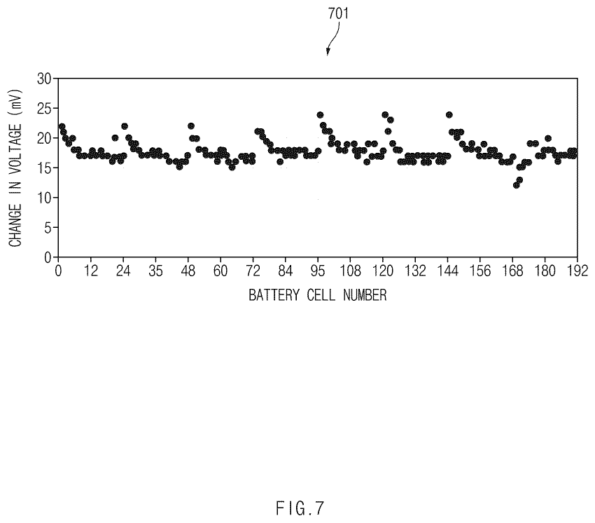

FIG. 7 illustrates an example of a degree of change in voltage according to a temperature of a battery cell, in a vehicle control apparatus, a vehicle control system, or a vehicle control method according to an exemplary embodiment of the present disclosure.

Referring to FIG. 7, a graph 701 may illustrate a difference in a change in voltage according to a position of a battery cell.

According to an exemplary embodiment of the present disclosure, a temperature of a battery cell located outside a battery and a temperature of a battery cell located inside the battery may be different from each other.

For example, immediately after an SOC value of the battery is included in a specified SOC indicating charging completion (e.g., at a time point within about 2 hours), the temperature of the battery cell located outside and the temperature of the battery located inside may be different from each other. Therefore, the accuracy of a diagnose performed based on a change in voltage during a specified time may be lowered.

Therefore, to improve the accuracy of the diagnosis, after the SOC value of the battery is included in the specified SOC indicating the charging completion, a processor of the vehicle control apparatus may fail to identify a change in voltage of each of the battery cells, during a third preliminary time interval, if a difference between the highest temperature and the lowest temperature among temperatures of the battery cells is greater than a specified temperature.

Referring to the graph 701, a change in voltage of the battery may vary with a position of the battery. If the temperature of air outside the battery is smaller than a temperature inside the battery like the winter season or the temperature inside the battery is greater than air outside the battery due to the driving of the host vehicle, because the temperature of the battery cell located outside the battery is small, the change in voltage of the battery cell located outside the battery may be identified to be greater than the change in voltage of the battery cell located inside the battery.

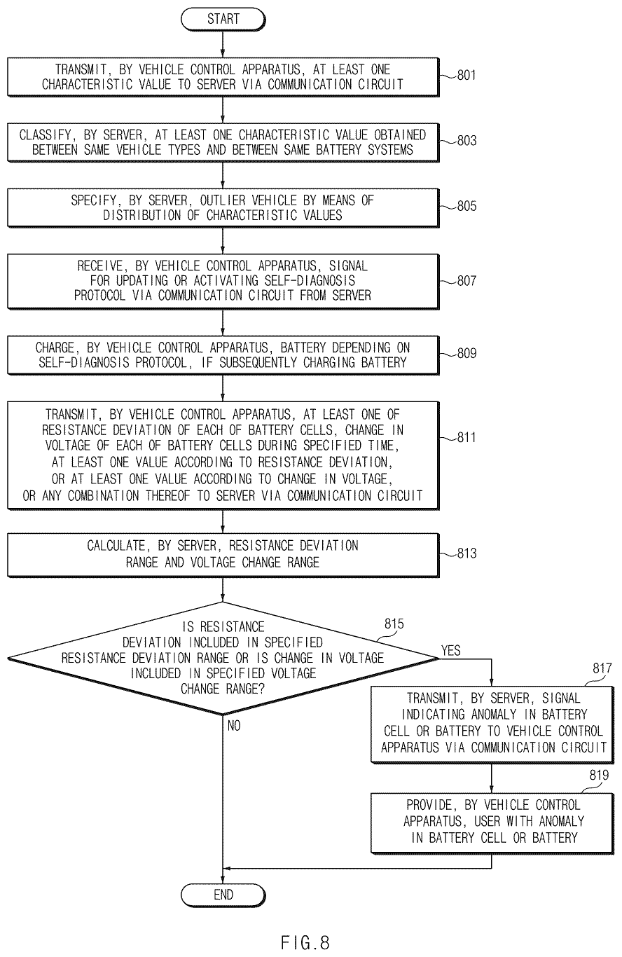

FIG. 8 illustrates an example of an operation of a vehicle control apparatus for providing a user with an anomaly in a battery cell or a battery, in the vehicle control apparatus, a vehicle control system, or a vehicle control method according to an exemplary embodiment of the present disclosure.

Hereinafter, it is assumed that a processor 107 of a vehicle control apparatus 101 of FIG. 1A or a processor of a vehicle control apparatus 111 of FIG. 1B is configured to perform a process of FIG. 8. Furthermore, in a description of FIG. 8, an operation described as being performed by a processor of a vehicle control apparatus may be understood as being controlled by the processor 107 of the vehicle control apparatus 101 or the processor of the vehicle control apparatus 111. Furthermore, in a description of FIG. 8, an operation described as being performed by a processor of a server may be understood as being controlled by a processor of a server 113.

Referring to FIG. 8, in a first operation 801, according to an exemplary embodiment of the present disclosure, the processor of the vehicle control apparatus may transmit at least one characteristic value to the server via a communication circuit.

According to an exemplary embodiment of the present disclosure, the least one characteristic value may include at least one characteristic value among standard deviations of voltages of battery cells, standard deviations of temperatures of the battery cells, standard deviations of SOCs of the battery cells, or standard deviations of SOHs of the battery cells, or any combination thereof.

In a second operation 803, according to an exemplary embodiment of the present disclosure, the processor of the server may classify the at least one characteristic value obtained between the same vehicle types and between the same battery systems.

In a third operation 805, according to an exemplary embodiment of the present disclosure, the processor of the server may specify an outlier vehicle by distribution of the characteristic values.

According to an exemplary embodiment of the present disclosure, the outlier vehicle may include a vehicle in which a probability of accident occurrence due to a battery (e.g., battery fire risk) is greater than a specified probability value.

According to an exemplary embodiment of the present disclosure, the processor of the server may identify that the vehicle control apparatus is included in the outlier vehicle, based on that the at least one characteristic value is included in a specified top percentage of characteristic values which correspond to the at least one characteristic value obtained from the vehicle control apparatus and are obtained from other vehicle control apparatus.

In a fourth operation 807, according to an exemplary embodiment of the present disclosure, the processor of the vehicle control apparatus may receive a signal for updating or activating a self-diagnosis protocol via the communication circuit from the server.

According to an exemplary embodiment of the present disclosure, the self-diagnosis protocol may indicate a protocol for identifying whether there is an anomaly in the battery cell or the battery.

In a fifth operation 809, according to an exemplary embodiment of the present disclosure, the processor of the vehicle control apparatus may charge the battery depending on the self-diagnosis protocol if subsequently charging the battery.

In a sixth operation 811, according to an exemplary embodiment of the present disclosure, the processor of the vehicle control apparatus may transmit at least one of a resistance deviation of each of the battery cells, a change in voltage of each of the battery cells during a specified time, at least one value according to the resistance deviation, or at least one value according to the change in voltage, or any combination thereof to the server via the communication circuit.

In a seventh operation 813, according to an exemplary embodiment of the present disclosure, the processor of the server may be configured to determine a resistance deviation range and a voltage change range.

In an eighth operation 815, according to an exemplary embodiment of the present disclosure, the processor of the server may identify whether the resistance deviation is included in the specified resistance deviation range or the change in voltage is included in the specified voltage change range. If the resistance deviation is included in the specified resistance deviation range or the change in voltage is included in the specified voltage change range, the processor of the server may perform a ninth operation 817. If the resistance deviation is not included in the specified resistance deviation range or the change in voltage is not included in the specified voltage change range, the processor of the server may end the operation.

In the ninth operation 817, according to an exemplary embodiment of the present disclosure, the processor of the server may transmit a signal indicating an anomaly in the battery cell or the battery to the vehicle control apparatus via the communication circuit.

In a tenth operation 819, according to an exemplary embodiment of the present disclosure, the processor of the vehicle control apparatus may provide a user with the anomaly in the battery cell or the battery.

According to an exemplary embodiment of the present disclosure, the processor of the vehicle control apparatus may provide the user with the anomaly in the battery cell or the battery, based on receiving the signal indicating the anomaly in the battery cell or the battery via the communication circuit from the server.

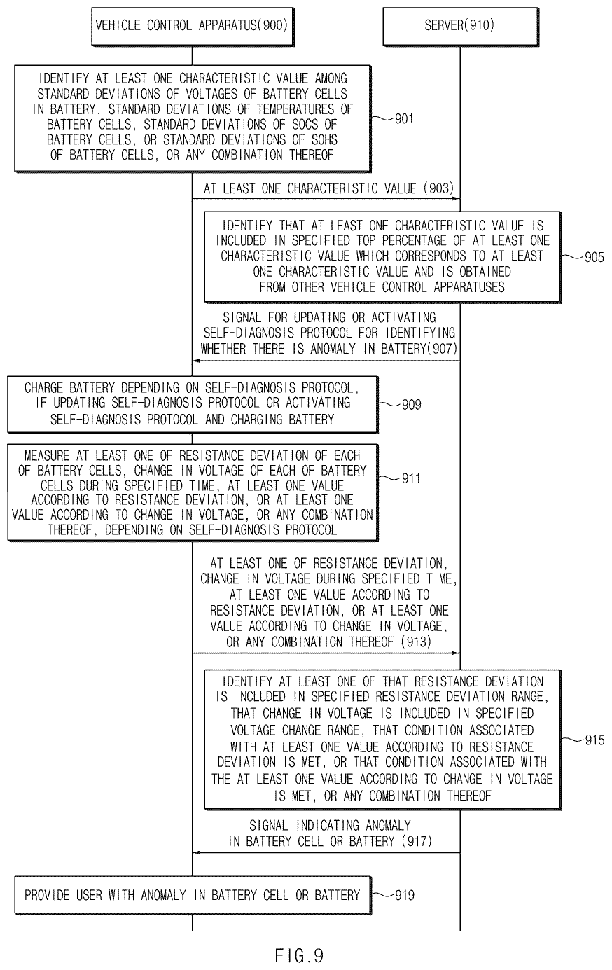

FIG. 9 illustrates an example of signaling between a vehicle control apparatus and a server, in the vehicle control apparatus, a vehicle control system, or a vehicle control method according to an exemplary embodiment of the present disclosure.

Hereinafter, it is assumed that a processor 107 of a vehicle control apparatus 101 of FIG. 1A or a processor of a vehicle control apparatus 111 of FIG. 1B is configured to perform a process of FIG. 9 and a processor of a server 113 of FIG. 1B is configured to perform the process of FIG. 9. Furthermore, in a description of FIG. 9, an operation described as being performed by a processor of a vehicle control apparatus may be understood as being controlled by the processor 107 of the vehicle control apparatus 101 or the processor of the vehicle control apparatus 111. Furthermore, in a description of FIG. 9, an operation described as being performed by a processor of a server may be understood as being controlled by the processor of the server 113.

Referring to FIG. 9, in a first operation 901, according to an exemplary embodiment of the present disclosure, a processor of a vehicle control apparatus 900 may identify at least one characteristic value among standard deviations of voltages of battery cells in a battery, standard deviations of temperatures of the battery cells, standard deviations of SOCs of the battery cells, or standard deviations of SOHs of the battery cells, or any combination thereof.

In a second operation 903, according to an exemplary embodiment of the present disclosure, the processor of the vehicle control apparatus 900 may transmit the at least one characteristic value to a server 910. A processor of the server 910 may receive the at least one characteristic value from the vehicle control apparatus 900.

In a third operation 905, according to an exemplary embodiment of the present disclosure, the processor of the server 910 may identify that the at least one characteristic value is included in a specified top percentage of at least one characteristic value which corresponds to the at least one characteristic value and is obtained from other vehicle control apparatuses.

In a fourth operation 907, according to an exemplary embodiment of the present disclosure, the processor of the server 910 may transmit a signal for updating or activating a self-diagnosis protocol for identifying whether there is an anomaly in the battery to the vehicle control apparatus 900. The processor of the vehicle control apparatus 900 may receive the signal for updating or activating the self-diagnosis protocol from the server 910.

In a fifth operation 909, according to an exemplary embodiment of the present disclosure, the processor of the vehicle control apparatus 900 may charge the battery depending on the self-diagnosis protocol, if updating the self-diagnosis protocol or activating the self-diagnosis protocol and charging the battery.

In a sixth operation 911, according to an exemplary embodiment of the present disclosure, the processor of the vehicle control apparatus 900 may measure at least one of a resistance deviation of each of the battery cells, a change in voltage of each of the battery cells during a specified time, at least one value according to the resistance deviation, or at least one value according to the change in voltage, or any combination thereof, depending on the self-diagnosis protocol.

In a seventh operation 913, according to an exemplary embodiment of the present disclosure, the processor of the vehicle control apparatus 900 may transmit the at least one of the resistance deviation, the change in voltage during the specified time, the at least one value according to the resistance deviation, or the at least one value according to the change in voltage, or the any combination thereof to the server 910 via the communication circuit. The processor of the server 910 may receive the at least one of the resistance deviation, the change in voltage during the specified time, the at least one value according to the resistance deviation, or the at least one value according to the change in voltage, or the any combination thereof from the vehicle control apparatus 900.

In an eighth operation 915, according to an exemplary embodiment of the present disclosure, the processor of the vehicle control apparatus 900 may identify at least one of that the resistance deviation is included in a specified resistance deviation range, that the change in voltage is included in a specified voltage change range, that a condition associated with the at least one value according to the resistance deviation is met, or that a condition associated with the at least one value according to the change in voltage is met, or any combination thereof.

In the ninth operation 917, according to an exemplary embodiment of the present disclosure, the processor of the server 910 may transmit a signal indicating an anomaly in the battery cell or the battery to the vehicle control apparatus 900. The processor of the vehicle control apparatus 900 may receive the signal for indicating the anomaly in the battery cell or the battery from the server 910.

In a tenth operation 919, according to an exemplary embodiment of the present disclosure, the processor of the vehicle control apparatus 900 may provide a user with the anomaly in the battery cell or the battery.

As the number of electric vehicles sold increases, the frequency of defects in electric vehicles is increasing. As the frequency of defects increases, preventing the risk of battery fire becomes important. To prevent battery fire, there is a need for a technology for continuously monitoring the battery and diagnosing an anomaly in the battery, while using the battery.

As the development of batteries becomes more advanced, because the constituent materials of battery cells and the configuration of the battery management system are changing rapidly, many resources are used to collect cases to set appropriate thresholds whenever a new model of the electric vehicle is released.

According to an exemplary embodiment of the present disclosure, the server may collect pieces of information of the battery management system of each of vehicle control apparatuses. The processor of the vehicle control apparatus may specify an outlier vehicle in which the probability of accident occurrence is greater than a specified probability and may update or activate the self-diagnosis protocol for the outlier vehicle, thus obtaining a threshold.

As electric vehicle sales increase, the resources (e.g., time, power, and computing resources) required for battery diagnosis are expected to rapidly increase. Therefore, according to an exemplary embodiment of the present disclosure, if a diagnosis is performed after filtering the need for diagnosis through statistical methods, resource savings may be secured.

Furthermore, the diagnosis only for the outlier vehicle is performed to improve the performance of electric vehicles.

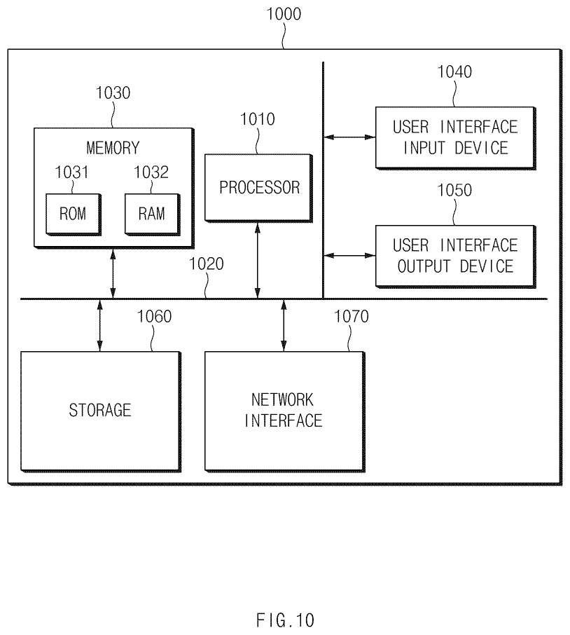

FIG. 10 illustrates a computing system associated with a vehicle control apparatus, a vehicle control system, or a vehicle control method according to an exemplary embodiment of the present disclosure.

Referring to FIG. 10, a computing system 1000 may include at least one processor 1010, a memory 1030, a user interface input device 1040, a user interface output device 1050, a storage 1060, and a network interface 1070, which are connected to each other via a bus 1020.

The processor 1010 may be a central processing unit (CPU) or a semiconductor device that processes instructions stored in the memory 1030 and/or the storage 1060. The memory 1030 and the storage 1060 may include various types of volatile or non-volatile storage media. For example, the memory 1030 may include a read only memory (ROM) 1031 and a random access memory (RAM) 1032.

Accordingly, the operations of the method or algorithm described in connection with the exemplary embodiments included in the specification may be directly implemented with a hardware module, a software module, or a combination of the hardware module and the software module, which is executed by the processor 1010. The software module may reside on a storage medium (that is, the memory 1030 and/or the storage 1060) such as a RAM, a flash memory, a ROM, an EPROM, an EEPROM, a register, a hard disc, a removable disk, and a CD-ROM.

The exemplary storage medium may be coupled to the processor 1010. The processor 1010 may read out information from the storage medium and may write information in the storage medium. Alternatively, the storage medium may be integrated with the processor 1010. The processor and the storage medium may reside in an application specific integrated circuit (ASIC). The ASIC may reside within a user terminal. In another case, the processor and the storage medium may reside in the user terminal as separate components.

The present technology may diagnose an anomaly in a battery cell or a battery.

Furthermore, the present technology may monitor and diagnose the battery, thus reducing the risk of battery fire.

Furthermore, the present technology may easily set a diagnosis threshold of the battery.

Furthermore, the present technology may perform a battery diagnosis by big data, thus improving the accuracy of the battery diagnosis.

Furthermore, the present technology may diagnose the battery, while proceeding with charging, thus improving a user experience.

Furthermore, the present technology may continuously monitor and diagnose the battery system, thus preventing fire.

Furthermore, the present technology may set an appropriate diagnosis threshold depending on the configuration of the battery system, which rapidly changes.

Furthermore, the present technology may reduce resources necessary to monitor the battery.

Furthermore, various effects ascertained directly or indirectly through the present disclosure may be provided.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, a plurality of operations may be merged, or any operation may be divided, and a specific operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operably may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A vehicle control apparatus, comprising:
a communication circuit;
a battery including battery cells; and
a processor operably connected to the communication circuit and the battery,
wherein the processor is configured to:
transmit at least one characteristic value among standard deviations of voltages of the battery cells, standard deviations of temperatures of the battery cells, standard deviations of states of charge (SOCs) of the battery cells, or standard deviations of states of health (SOHs) of the battery cells, or any combination thereof to a server via the communication circuit;
receive a signal for updating or activating a self-diagnosis protocol for identifying whether there is an anomaly in the battery cells or the battery via the communication circuit from the server, based on that the at least one characteristic value is included in a predetermined top percentage of characteristic values corresponding to the at least one characteristic value and obtained from other vehicle control apparatuses;
update the self-diagnosis protocol or activate the self-diagnosis protocol; and
perform charging depending on the self-diagnosis protocol, in charging the battery.

2. The vehicle control apparatus of claim 1, wherein the processor is further configured to:
perform charging depending on the self-diagnosis protocol, in charging the battery;
transmit at least one of a resistance deviation of each of the battery cells, the resistance deviation being obtained according to the updated or activated self-diagnosis protocol, a change in voltage of each of the battery cells during a predetermined time, the change in voltage being obtained according to the updated or activated self-diagnosis protocol, at least one value according to the resistance deviation, the at least one value being obtained according to the updated or activated self-diagnosis protocol, or at least one value according to the change in voltage, the at least one value being obtained according to the updated or activated self-diagnosis protocol, or any combination thereof to the server via the communication circuit, while charging the battery;
receive a signal indicating the anomaly in the battery cells or the battery via the communication circuit from the server, based on at least one of that the resistance deviation is included in a predetermined resistance deviation range, that the change in voltage is included in a predetermined voltage change range, the at least one value according to the resistance deviation, the at least one value according to the change in voltage, or any combination thereof; and
represent the anomaly in the battery cells or the battery to a user.

3. The vehicle control apparatus of claim 2, wherein the processor is further configured to:
rest the battery until a difference between a highest temperature and a lowest temperature among the temperatures of the battery cells is within a predetermined temperature difference, before charging the battery;
charge the battery with a first current by a predetermined SOC value, based on that the difference between the highest temperature and the lowest temperature is within the predetermined temperature difference;
rest the battery during a predetermined first time interval, from that the battery is charged by the predetermined SOC value, and obtain the resistance deviation of each of the battery cells, based on charging the battery with a second current greater than the first current during a predetermined second time interval, from that the predetermined first time interval elapses;
repeat charging the battery with the first current by the predetermined SOC value, resting the battery during the predetermined first time interval, charging the battery with the second current, and charging the battery during the predetermined second time interval, until an SOC value of the battery is included in a predetermined SOC range indicating charging completion; and
obtain the change in voltage of each of the battery cells during the predetermined time, based on resting the battery during a predetermined third time interval, from that the SOC value of the battery is included in the predetermined SOC range indicating the charging completion, and
wherein resting the battery indicates stopping supplying current provided from the outside of a host vehicle to the battery to charge the battery.

4. The vehicle control apparatus of claim 2, wherein the processor is further configured to:
rest the battery or adjust the temperatures of the battery cells by a cooling device provided in a host vehicle so that a difference between a highest temperature and a lowest temperature among the temperatures of the battery cells is within a predetermined temperature difference, before charging the battery.

5. The vehicle control apparatus of claim 3, wherein the processor is further configured to:
obtain the resistance deviation of each of the battery cells depending on at least one of a change in voltage of each of the battery cells according to the second current or resistance of each of the battery cells, or any combination thereof, based on charging the battery with the second current during the predetermined second time interval, from that the predetermined first time interval elapses.

6. The vehicle control apparatus of claim 3, wherein the processor is configured to:
obtain the resistance deviation of each of the battery cells to identify the anomaly in the battery cells or the battery due to a cause rather than an anomaly in electrolyte or active material included in the battery, during a predetermined first preliminary time interval, from that the battery starts to be charged with the second current; and
obtain the resistance deviation of each of the battery cells to identify the anomaly in the battery cells or the battery due to the anomaly in electrolyte or active material included in the battery, during a predetermined second preliminary time interval, from that the predetermined first preliminary time interval elapses, and
wherein the predetermined second preliminary time interval is identified according to a value obtained by subtracting the predetermined first preliminary time interval from the predetermined second time interval.

7. The vehicle control apparatus of claim 3, wherein the processor is further configured to:
obtain the resistance deviation of each of the battery cells to identify the anomaly in the battery cells or the battery due to a current path, while charging the battery with an SOC smaller than a reference SOC using the second current; and
obtain the resistance deviation of each of the battery cells to identify the anomaly in the battery cell or the battery due to the inside of the battery, while charging the battery with an SOC greater than the reference SOC using the second current.

8. The vehicle control apparatus of claim 3, wherein the processor is further configured to:
adjust a temperature of the battery or temperatures of at least some battery cells to be a predetermined temperature or higher, in resting the battery during the predetermined third time interval.

9. The vehicle control apparatus of claim 3, wherein the processor is further configured to:
obtain the change in voltage during a predetermined third preliminary time interval to identify at least one battery cell with resistance greater than resistance of other battery cells among the battery cells, from that the SOC value of the battery is included in the SOC range indicating the charging completion;
obtain a change in voltage during a predetermined fourth preliminary time interval to identify at least one battery cell in which there is a short circuit in an internal circuit among the battery cells, during the predetermined fourth preliminary time interval, from that the predetermined third preliminary time interval elapses, and
wherein the predetermined fourth preliminary time interval is identified according to a value obtained by subtracting the predetermined third preliminary time interval from the predetermined third time interval.

10. The vehicle control apparatus of claim 9, wherein the at least one battery cell in which there is the short circuit in the internal circuit among the battery cells is identified according to a change in SOC value of each of the battery cells, the change in SOC corresponding to an open circuit voltage (OCV) of each of the battery cells, based on obtaining the change in voltage including the OCV.

11. The vehicle control apparatus of claim 2, wherein the resistance deviation range is determined based on a resistance deviation of each of battery cells included in the other vehicle control apparatuses, and
wherein the voltage change range is determined based on a change in voltage of each of the battery cells included in the other vehicle control apparatuses.

12. A vehicle control system, comprising:
a vehicle control apparatus; and
a server,
wherein a processor included in the vehicle control apparatus is configured to:
transmit at least one characteristic value among standard deviations of voltages of battery cells in a battery included in the vehicle control apparatus, standard deviations of temperatures of the battery cells, standard deviations of states of charge (SOCs) of the battery cells, or standard deviations of states of health (SOHs) of the battery cells, or any combination to the server via a communication circuit included in the vehicle control apparatus;
receive a signal for updating or activating a self-diagnosis protocol for identifying whether there is an anomaly in the battery cells or the battery via the communication circuit included in the vehicle control apparatus from the server;
update the self-diagnosis protocol or activate the self-diagnosis protocol; and
perform charging depending on the self-diagnosis protocol, in charging the battery, and
wherein a processor included in the server is configured to:
transmit the signal for updating or activating the self-diagnosis protocol to the vehicle control apparatus via a communication circuit included in the server, based on that the at least one characteristic value is included in a predetermined top percentage of characteristic values corresponding to the at least one characteristic value and obtained from other vehicle control apparatuses.

13. The vehicle control system of claim 12, wherein the processor included in the vehicle control apparatus is further configured to:
perform charging depending on the self-diagnosis protocol, in charging the battery;
transmit at least one of a resistance deviation of each of the battery cells, the resistance deviation being obtained according to the updated or activated self-diagnosis protocol, a change in voltage of each of the battery cells during a predetermined time, the change in voltage being obtained according to the updated or activated self-diagnosis protocol, at least one value according to the resistance deviation, the at least one value being obtained according to the updated or activated self-diagnosis protocol, or at least one value according to the change in voltage, the at least one value being obtained according to the updated or activated self-diagnosis protocol, or any combination thereof to the server via the communication circuit included in the vehicle control apparatus, while charging the battery;
receive a signal indicating the anomaly in the battery cells or the battery via the communication circuit included in the vehicle control apparatus from the server; and
represent the anomaly in the battery cells or the battery to a user, and
wherein the processor included in the server is further configured to:
receive the at least one of the resistance deviation, the change in voltage, the at least one value according to the resistance deviation, or the at least one value according to the change in voltage, or the any combination thereof via the communication circuit included in the server from the vehicle control apparatus; and
transmit the signal indicating the anomaly in the battery cells or the battery to the vehicle control apparatus via the communication circuit included in the server, based on identifying at least one of that the resistance deviation is included in a predetermined resistance deviation range, that the change in voltage is included in a predetermined voltage change range, the at least one value according to the resistance deviation, or the at least one value according to the change in voltage, or any combination thereof.

14. The vehicle control system of claim 13, wherein the processor included in the server is further configured to:
identify the anomaly in the battery cells or the battery due to a cause rather than an anomaly in electrolyte or active material included in the battery, based on the resistance deviation obtained during a predetermined first preliminary time interval, from that the battery starts to be charged with a second current greater than a first current charged in the battery by a predetermined SOC; and
identify the anomaly in the battery cells or the battery due to the anomaly in electrolyte or active material included in the battery, based on the resistance deviation obtained during a predetermined second preliminary time interval, from that the predetermined first preliminary time interval elapses.

15. The vehicle control system of claim 13, wherein the processor included in the server is further configured to:
identify at least one battery cell with resistance greater than other battery cells among the battery cells, based on the change in voltage obtained during a predetermined third preliminary time interval, from that an SOC value of the battery is included in SOC range indicating charging completion; and
identify at least one battery cell in which there is a short circuit in an internal circuit among the battery cells, based on the change in voltage obtained during a predetermined fourth preliminary time internal, from that the predetermined third preliminary time interval elapses.

16. The vehicle control system of claim 15, wherein the processor included in the server is further configured to:
identify the at least one battery cell in which there is the short circuit in the internal circuit among the battery cells depending on an SOC value of each of the battery cells, the SOC corresponding to an open circuit voltage (OCV) of each of the battery cells, the OCV being included in the change in voltage, based on the OCV.

17. The vehicle control system of claim 13, wherein the processor included in the server is further configured to:
determine the resistance deviation range based on a resistance deviation of each of battery cells included in other vehicle control apparatuses; and
determine the voltage change range based on a change in voltage of each of the battery cells included in the other vehicle control apparatuses.

18. A method performed by a vehicle control apparatus, the method comprising:
transmitting at least one characteristic value among standard deviations of voltages of battery cells in a battery included in the vehicle control apparatus, standard deviations of temperatures of the battery cells, standard deviations of states of charge (SOCs) of the battery cells, or standard deviations of states of health (SOHs) of the battery cells, or any combination to a server via a communication circuit;
receiving a signal for updating or activating a self-diagnosis protocol for identifying whether there is an anomaly in the battery cells or the battery via the communication circuit from the server, based on that the at least one characteristic value is included in a predetermined top percentage of characteristic values corresponding to the at least one characteristic value and obtained from other vehicle control apparatuses;
updating the self-diagnosis protocol or activating the self-diagnosis protocol; and
performing charging depending on the self-diagnosis protocol, in charging the battery.

19. The method of claim 18, further including:
performing charging depending on the self-diagnosis protocol, in charging the battery;
transmitting at least one of a resistance deviation of each of the battery cells, the resistance deviation being obtained according to the updated or activated self-diagnosis protocol, a change in voltage of each of the battery cells during a predetermined time, the change in voltage being obtained according to the updated or activated self-diagnosis protocol, at least one value according to the resistance deviation, the at least one value being obtained according to the updated or activated self-diagnosis protocol, or at least one value according to the change in voltage, the at least one value being obtained according to the updated or activated self-diagnosis protocol, or any combination thereof to the server via the communication circuit, while charging the battery;
receiving a signal indicating the anomaly in the battery cells or the battery via the communication circuit from the server, based on at least one of that the resistance deviation is included in a predetermined resistance deviation range, that the change in voltage is included in a predetermined voltage change range, the at least one value according to the resistance deviation, or the at least one value according to the change in voltage, or any combination thereof; and
representing the anomaly in the battery cells or the battery to a user.

20. The method of claim 19, wherein the transmitting of the at least one of the resistance deviation of each of the battery cells, the resistance deviation being obtained according to the updated or activated self-diagnosis protocol, the change in voltage of each of the battery cells during the predetermined time, the change in voltage being obtained according to the updated or activated self-diagnosis protocol, the at least one value according to the resistance deviation, the at least one value being obtained according to the updated or activated self-diagnosis protocol, or the at least one value according to the change in voltage, the at least one value being obtained according to the updated or activated self-diagnosis protocol, or the any combination thereof to the server via the communication circuit, while charging the battery, includes:
resting the battery until a difference between a highest temperature and a lowest temperature among the temperatures of the battery cells is within a predetermined temperature difference, before charging the battery;
charging the battery with a first current by a predetermined SOC value, based on that the difference between the highest temperature and the lowest temperature is within the predetermined temperature difference;
resting the battery during a predetermined first time interval, from that the battery is charged by the predetermined SOC value, and obtaining the resistance deviation of each of the battery cells, based on charging the battery with a second current greater than the first current during a predetermined second time interval, from that the predetermined first time interval elapses;
repeating charging the battery with the first current by the predetermined SOC value, resting the battery during the predetermined first time interval, charging the battery with the second current, and charging the battery during the predetermined second time interval, until an SOC value of the battery is included in a predetermined SOC range indicating charging completion; and
obtaining the change in voltage of each of the battery cells during the predetermined time, based on resting the battery during a predetermined third time interval, from that the SOC value of the battery is included in the predetermined SOC range indicating the charging completion, and
wherein the resting of the battery indicates stopping supplying current provided from the outside of a host vehicle to the battery to charge the battery.

21. The method of claim 19, wherein the transmitting of the at least one of the resistance deviation of each of the battery cells, the resistance deviation being obtained according to the updated or activated self-diagnosis protocol, the change in voltage of each of the battery cells during the predetermined time, the change in voltage being obtained according to the updated or activated self-diagnosis protocol, the at least one value according to the resistance deviation, the at least one value being obtained according to the updated or activated self-diagnosis protocol, or the at least one value according to the change in voltage, the at least one value being obtained according to the updated or activated self-diagnosis protocol, or the any combination thereof to the server via the communication circuit, while charging the battery, includes:
resting the battery or adjusting the temperatures of the battery cells by a cooling device provided in a host vehicle so that a difference between a highest temperature and a lowest temperature among the temperatures of the battery cells is within a predetermined temperature difference, before charging the battery.

22. The method of claim 20, wherein the resting of the battery during the predetermined first time interval, from that the battery is charged by the predetermined SOC value, and the obtaining of the resistance deviation of each of the battery cells, based on charging the battery with the second current greater than the first current during the predetermined second time interval, from that the predetermined first time interval elapses, includes:
obtaining the resistance deviation of each of the battery cells depending on at least one of a change in voltage of each of the battery cells according to the second current or resistance of each of the battery cells, or any combination thereof, based on charging the battery with the second current during the predetermined second time interval, from that the predetermined first time interval elapses.

23. The method of claim 20, wherein the resting of the battery during the predetermined first time interval, from that the battery is charged by the predetermined SOC value, and the obtaining of the resistance deviation of each of the battery cells, based on charging the battery with the second current greater than the first current during the predetermined second time interval, from that the predetermined first time interval elapses, includes:
obtaining the resistance deviation of each of the battery cells to identify the anomaly in the battery cells or the battery due to a cause rather than an anomaly in electrolyte or active material included in the battery, during the predetermined first preliminary time interval, from that the battery starts to be charged with the second current; and
obtaining the resistance deviation of each of the battery cells to identify the anomaly in the battery cells or the battery due to the anomaly in electrolyte or active material included in the battery, during the predetermined second preliminary time interval, from that the predetermined first preliminary time interval elapses, and
wherein the predetermined second preliminary time interval is identified according to a value obtained by subtracting the predetermined first preliminary time interval from the predetermined second time interval.
